(19) United States
(12) Patent Application Publication
(10) Pub. No.: US 2026/0119759 A1
(43) Pub. Date: Apr. 30, 2026

(54) PSEUDO-FLUID MODEL-BASED NUMERICAL SIMULATION METHOD FOR DEEP-SEA MINING AND RELATED DEVICES

(71) Applicant: CHINA UNIVERSITY OF PETROLEUM-BEIJING, Beijing (CN)

(72) Inventors: Yingying WANG, Beijing (CN); Zhuo CHENG, Beijing (CN); Ke WANG, Beijing (CN); Bolin LIU, Beijing (CN); Chuanbo CONG, Beijing (CN); Haibo SUN, Beijing (CN); Yufang LI, Beijing (CN)

(21) Appl. No.: 19/284,387

(22) Filed: Jul. 29, 2025

(30) Foreign Application Priority Data
Oct. 31, 2024 (CN) 202411547966.7

(51) Int. Cl. G06F 30/28

(52) U.S. Cl. CPC G06F 30/28

(57) ABSTRACT

A pseudo-fluid model-based numerical simulation method for deep-sea mining and related devices are disclosed. In the above method, first, an initial velocity field, an initial pressure field, and an initial particle concentration distribution in a deep-sea mining pipeline are set; then, boundary conditions at an inlet and an outlet of the deep-sea mining pipeline are defined; and finally, numerical simulation is performed on the deep-sea mining pipeline by using a pseudo-fluid model to obtain a deep-sea mining numerical simulation result, where the deep-sea mining numerical simulation result includes a pressure distribution, a velocity field, a particle concentration distribution, an effective density, and an effective viscosity. During the process, solid particles are simplified into a pseudo-fluid by using the pseudo-fluid model, and effective density and effective viscosity are introduced. Numerical simulation is performed on the deep-sea mining pipeline based on the effective density and the effective viscosity.

### CROSS-REFERENCE TO RELATED APPLICATIONS

The present application claims priority to Chinese Patent Application No. 202411547966.7, titled “PSEUDO-FLUID MODEL-BASED NUMERICAL SIMULATION METHOD FOR DEEP-SEA MINING AND RELATED DEVICES”, filed on Oct. 31, 2024 with the China National Intellectual Property Administration, which is incorporated herein by reference in its entirety.

### FIELD

The present disclosure relates to the technical field of numerical simulations, and in particular to a pseudo-fluid model-based numerical simulation method for deep-sea mining and related devices.

### BACKGROUND

Deep-sea mining is a technology for exploiting minerals from the seabed and transporting the minerals to the sea surface. In the technical field of deep-sea mining, numerical simulation of a solid-fluid two-phase flow is required to explore a suitable flow field solution for a mining head. However, due to complex conditions of a deep-sea environment, numerical simulation of the solid-liquid two-phase flow is extremely complex.

With methods adopted in the conventional art, detailed information of particle motion is obtained. However, the methods have low computational efficiency and high resource consumption due to algorithmic computation issues.

### SUMMARY

A pseudo-fluid model-based numerical simulation method for deep-sea mining and related devices are provided according to the present disclosure. Solid particles are simplified into a pseudo-fluid by using a pseudo-fluid model to avoid detailed tracking of particle collisions and motions, so as to reduce computational complexity and improve the efficiency of numerical simulation.

In a first aspect, a pseudo-fluid model-based numerical simulation method for deep-sea mining is provided according to the present disclosure, and the pseudo-fluid model-based numerical simulation method includes:
setting an initial velocity field, an initial pressure field, and an initial particle concentration distribution in a deep-sea mining pipeline;
defining boundary conditions at an inlet and an outlet of the deep-sea mining pipeline; and

performing numerical simulation on the deep-sea mining pipeline by using a pseudo-fluid model, to obtain a deep-sea mining numerical simulation result, where the deep-sea mining numerical simulation result includes a pressure distribution, a velocity field, a particle concentration distribution, an effective density, and an effective viscosity.

In an embodiment, the pseudo-fluid model is constructed by:
performing a weighted average calculation on a density of solid particles and a density of a fluid according to a particle volume fraction to obtain an effective density;
obtaining an effective viscosity based on the particle volume fraction and a viscosity of a base fluid;
determining a Navier-Stokes equation for the pseudo-fluid model based on the effective density and the effective viscosity

$${ρ}_{eff} ( \frac{\partial u}{\partial t} + u \cdot ∇ u ) = - ∇ p + ∇ \cdot [ {μ}_{eff} ( ∇ u + {( ∇ u )}^{T} ) ] + {ρ}_{eff} g + {F}_{v i b}$$

where ρ_{eff} represents an effective density; U represents a velocity field; ∇ represents divergence or contraction of a vector field in space; t represents time, and

$$\frac{\partial u}{\partial t}$$

represents a change rate of the velocity field with respect to time; P represents a pressure field; μ_{eff} represents an effective viscosity; g represents gravity; and F_{vib} represents an impact of an external vibrational force applied to the fluid on the velocity field;
constructing a convection-diffusion equation based on the particle volume fraction, where the convection-diffusion equation is expressed as

$$\frac{\partial ϕ}{\partial t} + ∇ \cdot ( ϕ u ) = ∇ \cdot ( {D}_{ϕ} ∇ ϕ )$$

where φ represents a scalar field;

$$\frac{\partial ϕ}{\partial t}$$

represents a change rate of the scalar field φ with respect to time; u represents the velocity field; V represents a divergence operator; and D_{φ} represents a diffusion coefficient, which describes a diffusivity of the scalar field φ; and
constructing a pipeline vibration model of a beam, where a vibration displacement equation for the beam in the pipeline vibration model of the beam is expressed as

$$EI \frac{{\partial }^{4} w}{\partial {z}^{4}} + {ρ}_{A} \frac{{\partial }^{2} w}{\partial {t}^{2}} = {F}_{vib} ( z , t ) + {F}_{C o r} + {F}_{Cen}$$

where E represents an elastic modulus; I represents an area moment of inertia; EI represents bending stiffness of the beam;

$$\frac{{\partial }^{4} w}{\partial {z}^{4}}$$

represents a variation of deflection of the beam with a beam length; ρ_{A} represents a linear density;

$$\frac{{\partial }^{2} w}{\partial {t}^{2}}$$

represents a second derivative of the deflection with respect to time, that is, an acceleration of the beam; F_{vib}(z,t) represents a distributed load along a pipeline length; F_{Cor} represents a Coriolis force; and F_{Cen} represents a centrifugal force.

In an embodiment, the performing numerical simulation on the deep-sea mining pipeline by using a pseudo-fluid model, to obtain a deep-sea mining numerical simulation result includes:
discretizing the Navier-Stokes equation, the convection-diffusion equation, and a vibration governing equation for the beam to obtain discrete equations; and
solving the discrete equations through a high-precision iterative method to obtain the deep-sea mining numerical simulation result.

In an embodiment, the solving the discrete equations through a high-precision iterative method to obtain the deep-sea mining numerical simulation result includes:
obtaining a predicted velocity field based on the discrete equations, the effective density, the effective viscosity, and a velocity field formula, where the predicted velocity field is expressed as

$$u = {u}^{n} - Δ t ( {u}^{n} \cdot ∇ {u}^{n} + \frac{∇ {p}^{n}}{{ρ}_{eff}} - \frac{∇ \cdot [ {μ}_{eff} ( ∇ {u}^{n} + {( ∇ {u}^{n} )}^{T} ) ]}{{ρ}_{eff}} ) + Δ t {F}_{vib}$$

where u represents the velocity field; uⁿ represents a value of the velocity field at a previous time step; Δt represents a time step size; uⁿ·∇uⁿ represents a convective term of the velocity field; ρ_{eff} represents the effective density; ∇pⁿ represents a pressure gradient term; μ_{eff} represents the effective viscosity; ∇·[μ_{eff}(∇uⁿ+(∇uⁿ)^{T})] represents a viscous force term; and F_{vib} represents the impact of the external vibrational force applied to the fluid on the velocity field;
substituting the predicted velocity field into a continuity equation to obtain a pressure correction equation, and the pressure correction equation is expressed as

$${A}_{p} {p}^{′} = b$$

where Aₚ represents a pressure correction coefficient matrix; p′ represents a pressure correction value; and b represents a source term vector;
updating the velocity field, the pressure field, and a vibration displacement of the beam based on the pressure correction equation;
updating the effective density and the effective viscosity based on the updated velocity field and particle concentration distributions at different time steps; and
repeatedly performing the operations from obtaining the predicted velocity field to updating the effective density and the effective viscosity until variations of the velocity field and the pressure field satisfy a convergence criterion, to obtain the deep-sea mining numerical simulation result.

In an embodiment, the updating the effective density and the effective viscosity based on the updated velocity field and particle concentration distributions at different time steps includes:
measuring a density and a viscosity of a solid-fluid mixture by means of an experimental apparatus to determine a standard effective density and a standard effective viscosity;
calculating an error by comparing the effective density with the standard effective density and comparing the effective viscosity with the standard effective viscosity; and
continuing, in response to the error being greater than a predetermined value, to the process of updating the effective density and the effective viscosity based on the updated velocity field and particle concentration distributions at different time steps.

In an embodiment, the defining boundary conditions at an inlet and an outlet of the deep-sea mining pipeline includes:
defining a fixed flow velocity and a fixed particle concentration for the inlet of the deep-sea mining pipeline; and
defining a fixed pressure for the outlet of the deep-sea mining pipeline.

In a second aspect, a pseudo-fluid model-based numerical simulation apparatus for deep-sea mining is provided according to the present disclosure, and the pseudo-fluid model-based numerical simulation apparatus includes a setting unit, a definition unit, and a numerical simulation unit.

The setting unit is configured to set an initial velocity field, an initial pressure field, and an initial particle concentration distribution in a deep-sea mining pipeline.

The definition unit is configured to define boundary conditions at an inlet and an outlet of the deep-sea mining pipeline.

The numerical simulation unit is configured to perform numerical simulation on the deep-sea mining pipeline by using a pseudo-fluid model, to obtain a deep-sea mining numerical simulation result. The deep-sea mining numerical simulation result includes a pressure distribution, a velocity field, a particle concentration distribution, an effective density, and an effective viscosity.

In an embodiment, the pseudo-fluid model-based numerical simulation apparatus further includes an obtaining unit, a determination unit, and a construction unit.

The obtaining unit is configured to perform a weighted average calculation on a density of solid particles and a density of a fluid according to a particle volume fraction to obtain the effective density, and obtain the effective viscosity based on the particle volume fraction and a viscosity of a base fluid.

The determination unit is configured to determine a Navier-Stokes equation for the pseudo-fluid model based on the effective density and the effective viscosity:

$${ρ}_{eff} ( \frac{\partial u}{\partial t} + u \cdot ∇ u ) = - ∇ p + ∇ \cdot [ {μ}_{eff} ( ∇ u + {( ∇ u )}^{T} ) ] + {ρ}_{eff} g + {F}_{vi b}$$

where ρ_{eff} represents an effective density, u represents a velocity field, ∇ represents divergence or contraction of a vector field in space; t represents time, and

$$\frac{\partial u}{\partial t}$$

represents a change rate of the velocity field with respect to time; p represents a pressure field; μ_{eff} represents an effective viscosity; g represents gravity; and F_{vib} represents an impact of an external vibrational force applied to the fluid on the velocity field.

The construction unit is configured to construct a convection-diffusion equation based on the particle volume fraction, where the convection-diffusion equation is expressed as

$$\frac{\partial ϕ}{\partial t} + ∇ \cdot ( ϕ u ) = ∇ \cdot ( {D}_{ϕ} ∇ ϕ )$$

where φ represents a scalar field,

$$\frac{\partial ϕ}{\partial t}$$

represents a change rate of the scalar field φ with respect to time, u represents the velocity field, ∇ represents a divergence operator, and D_{φ} represents a diffusion coefficient, which describes a diffusivity of the scalar field φ.

The construction unit is further configured to construct a pipeline vibration model of a beam, where a vibration displacement equation for the beam in the pipeline vibration model of the beam is expressed as

$$EI \frac{{\partial }^{4} w}{\partial {z}^{4}} + {ρ}_{A} \frac{{\partial }^{2} w}{\partial {t}^{2}} = {F}_{vib} ( z , t ) + {F}_{C o r} + {F}_{Cen}$$

where E represents an elastic modulus; I represents an area moment of inertia; EI represents bending stiffness of the beam;

$$\frac{{\partial }^{4} w}{\partial {t}^{4}}$$

represents a variation of deflection of the beam with a beam length; ρ_{A} represents a linear density;

$$\frac{{\partial }^{2} w}{\partial {t}^{2}}$$

represents a second derivative of the deflection with respect to time, that is, an acceleration of the beam; F_{vib}(z,t) represents a distributed load along a pipeline length; F_{Cor} represents a Coriolis force; and F_{Cen} represents a centrifugal force.

In an embodiment, the numerical simulation unit further includes a conversion subunit and a solution subunit.

The conversion subunit is configured to discretize the Navier-Stokes equation, the convection-diffusion equation, and the vibration governing equation for the beam to obtain discrete equations.

The solution subunit is configured to solve the discrete equations by using a high-precision iterative method to obtain the deep-sea mining numerical simulation result.

In an embodiment, the solution subunit is further configured to:
obtain a predicted velocity field based on the discrete equations, the effective density, the effective viscosity, and a velocity field formula, where the predicted velocity field is expressed as

$$u = {u}^{n} - Δ t ( {u}^{n} \cdot ∇ {u}^{n} + \frac{∇ {p}^{n}}{{ρ}_{eff}} - \frac{∇ \cdot [ {μ}_{eff} ( ∇ {u}^{n} + {( ∇ {u}^{n} )}^{T} ) ]}{{ρ}_{eff}} ) + Δ t {F}_{v i b}$$

where u represents the velocity field; uⁿ represents a value of the velocity field at a previous time step; Δt represents a time step size; uⁿ·∇uⁿ represents a convective term of the velocity field; ρ_{eff} represents the effective density; ∇pⁿ represents a pressure gradient term; μ_{eff} represents the effective viscosity; ∇·[μ_{eff}(∇uⁿ+(∇uⁿ)^{T})] represents a viscous force term; and F_{vib} represents an impact of an external vibrational force applied to the fluid on the velocity field;
substitute the predicted velocity field into a continuity equation to obtain a pressure correction equation, and the pressure correction equation is expressed as

$${A}_{p} {p}^{′} = b$$

where Aₚ represents a pressure correction coefficient matrix; p′ represents a pressure correction value; and b represents a source term vector;
update the velocity field, the pressure field, and a vibration displacement of the beam based on the pressure correction equation;
update the effective density and the effective viscosity based on the updated velocity field and particle concentration distributions at different time steps; and
repeatedly perform the operations from obtaining the predicted velocity field to updating the effective density and the effective viscosity until variations of the velocity field and the pressure field satisfy a convergence criterion, to obtain the deep-sea mining numerical simulation result.

In an embodiment, for updating the effective density and the effective viscosity based on the updated velocity field and particle concentration distributions at different time steps, the solution subunit is further configured to:
measure a density and a viscosity of a solid-fluid mixture by means of an experimental apparatus to determine a standard effective density and a standard effective viscosity;
calculate an error by comparing the effective density with the standard effective density and comparing the effective viscosity with the standard effective viscosity; and
continue, in response to the error being greater than a predetermined value, to the process of updating the effective density and the effective viscosity based on the updated velocity field and particle concentration distributions at different time steps.

In an embodiment, the definition unit is further configured to:
define a fixed flow velocity and a fixed particle concentration for the inlet of the deep-sea mining pipeline; and
define a fixed pressure for the outlet of the deep-sea mining pipeline.

In a third aspect, an electronic device is provided according to the present disclosure. The electronic device includes a memory and a processor.

The memory stores a computer program.

The processor is configured to execute the computer program to perform the pseudo-fluid model-based numerical simulation method provided in the first aspect described above.

In a fourth aspect, a computer-readable storage medium is further provided according to the present disclosure. The computer-readable storage medium stores a computer program. The computer program is executed to perform the method provided in the first aspect described above.

It can be seen that the present disclosure has the following beneficial effects.

A pseudo-fluid model-based numerical simulation method for deep-sea mining is provided according to the present disclosure. First, an initial velocity field, an initial pressure field, and an initial particle concentration distribution in a deep-sea mining pipeline are set. Then, boundary conditions at an inlet and an outlet of the deep-sea mining pipeline are defined. Finally, numerical simulation is performed on the deep-sea mining pipeline by using a pseudo-fluid model, to obtain a deep-sea mining numerical simulation result, where the deep-sea mining numerical simulation result includes a pressure distribution, a velocity field, a particle concentration distribution, an effective density, and an effective viscosity. During the process, solid particles are simplified into a pseudo-fluid by using the pseudo-fluid model, and an effective density and an effective viscosity are introduced. Numerical simulation is performed on the deep-sea mining pipeline based on the effective density and the effective viscosity, and compared with conventional algorithmic computations, computational complexity is simplified and numerical simulation efficiency is improved.

### BRIEF DESCRIPTION OF THE DRAWINGS

In order to clearly describe the technical solutions in the embodiments of the present disclosure, drawings to be used in the description of the embodiments of the present disclosure are briefly described hereinafter. It is apparent that the drawings described below are merely used for describing the embodiments of the present disclosure, and those skilled in the art may obtain other drawings according to the provided drawings.

FIG. 1 is a flowchart illustrating a pseudo-fluid model-based numerical simulation method for deep-sea mining according to an embodiment of the present disclosure;

FIG. 2 is a flowchart illustrating a pseudo-fluid model-based numerical simulation method for deep-sea mining according to another embodiment of the present disclosure;

FIG. 3 is a schematic diagram of a pseudo-fluid model according to an embodiment of the present disclosure;

FIG. 4 is a schematic diagram of a pipeline vibration model according to an embodiment of the present disclosure;

FIG. 5 is a schematic structural diagram of a pseudo-fluid model-based numerical simulation apparatus for deep-sea mining according to an embodiment of the present disclosure; and

FIG. 6 is a schematic structural diagram of an electronic device according to an embodiment of the present disclosure.

### DETAILED DESCRIPTION

The technical solutions according to the embodiments of the present disclosure will be described clearly and completely as follows in conjunction with the drawings in the embodiments of the present disclosure. It is apparent that the described embodiments are only some of the embodiments according to the present disclosure, rather than all the embodiments. All other embodiments obtained by those skilled in the art based on the embodiments of the present disclosure without any creative work fall within the protection scope of the present disclosure.

It should be noted that the user information (including but not limited to user device information and user personal information) and data (including but not limited to to-be-analyzed data, stored data, and displayed data) involved in the present disclosure are all authorized by the user or fully authorized by all related parties. In addition, the collection, usage and processing of the relevant data comply with relevant laws, regulations, and standards of relevant countries and regions.

Currently, due to complex conditions of high pressure, low temperature, and strong ocean currents in a deep-sea environment, numerical simulation for a solid-fluid two-phase flow has become extremely complex. Through conventional technologies such as the discrete element method (DEM) and the Euler-Lagrange method, detailed information of particle motion is obtained. However, when these algorithms are actually applied for numerical simulation, the computational efficiency is low, and the computational resource consumption is high.

In the embodiments of the present disclosure, solid particles are simplified into a pseudo-fluid by using a pseudo-fluid model. The solid particles are treated as a pseudo fluid with effective density and effective viscosity, avoiding detailed tracking of particle collisions and motions, and thereby reducing computational complexity and increasing the efficiency of numerical simulation.

In an implementation, for example, the pseudo-fluid model-based numerical simulation method for deep-sea mining includes: setting an initial velocity field, an initial pressure field, and an initial particle concentration distribution in a deep-sea mining pipeline; defining boundary conditions at an inlet and an outlet of the deep-sea mining pipeline; and then performing numerical simulation on the deep-sea mining pipeline by using a pseudo-fluid model to obtain a deep-sea mining numerical simulation result. The deep-sea mining numerical simulation result includes a pressure distribution, a velocity field, a particle concentration distribution, an effective density, and an effective viscosity.

It can be seen that, in the pseudo-fluid model-based numerical simulation method according to the embodiment of the present disclosure, solid particles are simplified into a pseudo-fluid by using the pseudo-fluid model, and an effective density and an effective viscosity are introduced. Numerical simulation is performed on a deep-sea mining pipeline based on the effective density and the effective viscosity. Compared with computation of conventional algorithms, computational complexity is reduced and numerical simulation efficiency is improved according to the method in the present disclosure.

To facilitate understanding of a specific implementation of the pseudo-fluid model-based numerical simulation method for deep-sea mining according to an embodiment of the present disclosure, the following description will be made with reference to the accompanying drawings.

It should be noted that an execution subject for implementing the pseudo-fluid model-based numerical simulation method for deep-sea mining may be a pseudo-fluid model-based numerical simulation apparatus for deep-sea mining according to an embodiment of the present disclosure. The pseudo-fluid model-based numerical simulation apparatus for deep-sea mining may be embedded in an electronic device or a functional module of an electronic device. The electronic device according to an embodiment of the present disclosure may be any device which is capable of implementing pseudo-fluid model-based numerical simulation method for deep-sea mining according to the embodiment of the present disclosure, such as an Internet of Things (IoT) device.

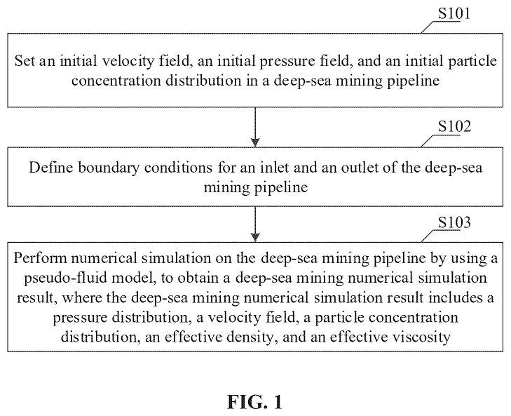

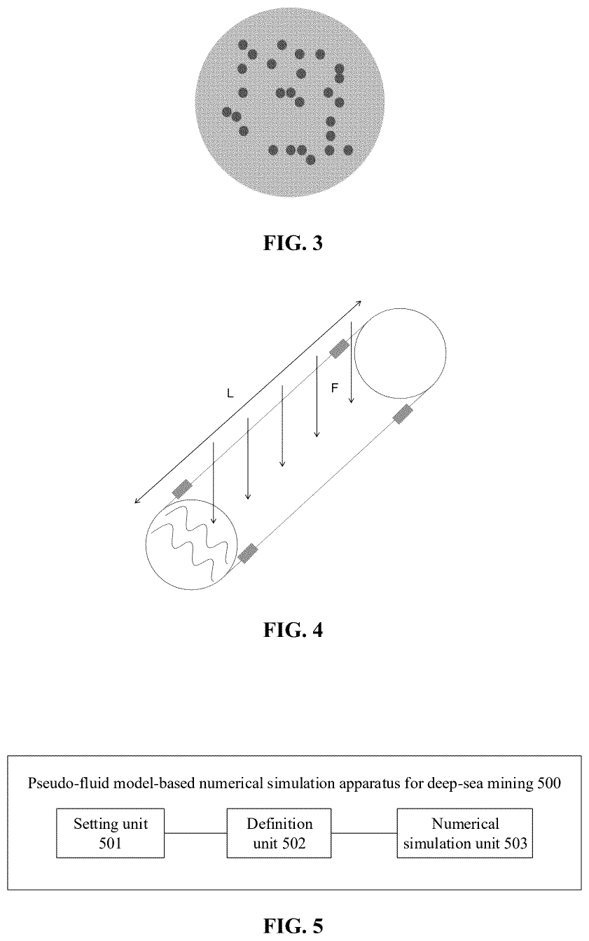

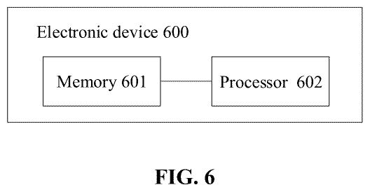

FIG. 1 is a flowchart illustrating a pseudo-fluid model-based numerical simulation method for deep-sea mining according to an embodiment of the present disclosure. The method may be applied to a pseudo-fluid model-based numerical simulation apparatus for deep-sea mining. The pseudo-fluid model-based numerical simulation apparatus for deep-sea mining may, for example, be a pseudo-fluid model-based numerical simulation apparatus 500 for deep-sea mining shown in FIG. 5, or the pseudo-fluid model-based numerical simulation apparatus for deep-sea mining may be a functional module integrated into an electronic device 600 shown in FIG. 6.

As shown in FIG. 1, the pseudo-fluid model-based numerical simulation method includes the following steps S101 to S103.

In step S101, an initial velocity field, an initial pressure field, and an initial particle concentration distribution in a deep-sea mining pipeline are set.

To obtain a deep-sea mining numerical simulation result, in the embodiment of the present disclosure, first, an initial velocity field, an initial pressure field, and an initial particle concentration distribution in the deep-sea mining pipeline are set; then, boundary conditions at an inlet and an outlet of the deep-sea mining pipeline are defined; and finally, numerical simulation is performed on the deep-sea mining pipeline by using a pseudo-fluid model, to obtain a deep-sea mining numerical simulation result. The deep-sea mining numerical simulation result includes a pressure distribution, a velocity field, a particle concentration distribution, an effective density, and an effective viscosity. In this embodiment of the present disclosure, step S101 is performed to make preparations for subsequent numerical simulation.

During the process, for performing the numerical simulation, the initial conditions are set first, that is, the initial velocity field, the initial pressure field, and the initial particle concentration distribution in the deep-sea mining pipeline are set. This ensures that the simulation converges and remains consistent with physical laws when the subsequent numerical simulation is performed. Improperly set initial conditions may lead to divergence during the simulation process, that is, the computation result is unstable or fails to converge. For example, in a fluid dynamics simulation, an improperly set initial velocity field may cause numerical oscillations or computation failures during the computational process. Properly set initial conditions reduce iterations during the computational process and improve computation efficiency.

In step S102, boundary conditions at an inlet and an outlet of the deep-sea mining pipeline are defined.

Boundary conditions are an indispensable part of the numerical simulation, and variation rules of variables or derivatives of the variables at boundaries of a solution domain are defined through the boundary conditions. In the setting for the numerical simulation according to the embodiment of the present disclosure, the boundary conditions at the inlet and the outlet of the deep-sea mining pipeline are set according to specific simulation requirements and physical phenomena. Two typical settings are described as follows.

### (1) A Flow Velocity, a Pressure and a Particle Concentration are Set for the Inlet and a Flow Velocity, a Pressure and a Particle Concentration are Set for the Outlet.

In this case, values of the flow velocity, the pressure, and the particle concentration at the inlet and at the outlet of the deep-sea mining pipeline are set. The setting typically serves to control a detailed state of an entire flow system, enabling a simulator to precisely control an entire process of a fluid from entering to exiting the system. This setting is typically used in investigation of complex interactions or reactions of the fluid between the inlet and the outlet.

### (2) A Fixed Flow Velocity and a Fixed Particle Concentration are Set for the Inlet, and a Fixed Pressure is Set for the Outlet.

In this case, the flow velocity and the particle concentration at the inlet of the deep-sea mining pipeline are set to fixed values, and the pressure at the outlet is set to a fixed value. This is a more common boundary condition setting, suitable for various fluid dynamics simulation, and in particular for industrial applications, such as pipeline flow and chemical processes. This boundary condition setting simplifies the simulation, and enables a more focused investigation of behaviors of the fluid within the pipeline or a device rather than a detailed state of the fluid at the outlet.

In an embodiment, the second setting is selected in the present disclosure. Step S102 includes: defining a fixed flow velocity and a fixed particle concentration for the inlet of the deep-sea mining pipeline; and defining a fixed pressure for the outlet of the deep-sea mining pipeline.

In step S103, numerical simulation is performed on the deep-sea mining pipeline by using a pseudo-fluid model, to obtain a deep-sea mining numerical simulation result, where the deep-sea mining numerical simulation result includes a pressure distribution, a velocity field, a particle concentration distribution, an effective density, and an effective viscosity.

In the embodiment of the present disclosure, a pseudo-fluid model is used to simulate particle effects in a solid-fluid mixed flow, with an impact from particle collisions ignored. By using the model, normalization is performed on solid particles and the fluid, and the solid particles and the fluid are treated as a pseudo-fluid with an effective density and an effective viscosity, thereby simplifying a computational process.

In a solid-fluid mixed flow simulation, the effective density is an important parameter which determines an inertial characteristic of the fluid. The effective density is calculated by performing weighted average calculation on densities of the solid particles and of the fluid, as well as a volume fraction of the particles in the fluid. The effective density affects an inertial term in a fluid dynamics equation, and thus directly affects the calculation of the velocity field and pressure field. The effective viscosity describes an internal friction characteristic of the fluid, and in particular of the fluid containing suspended particles. The effective viscosity is determined by incorporating the effects of the solid particles. In the numerical simulation, the effective viscosity affects a viscous dissipation term in the Navier-Stokes equation and is crucial for a damping effect on fluid velocity gradients.

In an embodiment, a process of constructing the pseudo-fluid model in the embodiment of the present disclosure includes following (1) to (5).
(1) Weighted average calculation is performed on the density of the solid particles and the density of the fluid according to the particle volume fraction to obtain an effective density. The calculation formula of the effective density is expressed as follows:

$${ρ}_{eff} = {ϕρ}_{s} + ( 1 - ϕ ) {ρ}_{f}$$

where ρ_{eff} represents the effective density; φ represents the particle volume fraction; ρₛ represents the density of the solid particles; and ρ_{f} represents the density of the fluid.
(2) An effective viscosity is obtained based on the particle volume fraction and a viscosity of a base fluid, where the effective viscosity represents an overall viscosity of the solid-fluid mixture and can be preliminarily estimated through an Einstein equation, and the equation for preliminary estimation is expressed as follows:

$${μ}_{eff} = {μ}_{f} ( 1 + 2.5 ϕ )$$

where μ_{eff} represents the effective viscosity; φ represents the particle volume fraction; and μ_{f} represents the viscosity of the base fluid.
For the solid-fluid mixture with solid particles in relatively high concentrations, the effective viscosity is determined through a modified empirical equation or experimental data, such as a Krieger-Dougherty equation:

$${μ}_{eff} = {{μ}_{f} ( 1 - \frac{ϕ}{{ϕ}_{m}} )}^{- 2.5 {ϕ}_{m}}$$

where μ_{eff} represents the effective viscosity; μ_{f} represents the viscosity of the base fluid; φ represents the particle volume fraction; and φₘ represents a maximum volume fraction of the solid particles.

The above-described Krieger-Dougherty equation is commonly applied in researches related to suspended fluids or particle-enhanced fluids for calculation of the effective viscosity.
(3) The Navier-Stokes equation for the pseudo-fluid model is determined based on the effective density and effective viscosity as follows:

$${ρ}_{eff} ( \frac{\partial u}{\partial t} + u \cdot ∇ u ) = - ∇ p + ∇ \cdot [ {μ}_{eff} ( ∇ u + {( ∇ u )}^{T} ) ] + {ρ}_{eff} g + {F}_{vib}$$

where ρ_{eff} represents the effective density; u represents the velocity field; ∇ is used to describe how a vector field (such as the velocity field) diverges or converges in space, representing the net outflow rate of a substance (such as the fluid) in a vicinity of a given point; t represents time, that is,

$$\frac{\partial u}{\partial t}$$

represents a change rate of the velocity field with respect to time; p represents the pressure field; μ_{eff} represents the effective density; g represents gravity; and F_{vib} represents an impact of an external vibrational force applied in the fluid on the velocity field.

In the embodiment of the present disclosure, a Hamilton's principle of virtual work is adopted to derive a momentum equation of the system. By substituting kinetic energy, potential energy, and work done by external forces (a pressure, a viscous force, and a pipeline vibration force) into Hamilton's principle of virtual work and performing variational derivation and rearrangement, the momentum equation is obtained as the above-described Navier-Stokes equation.
(4) To describe motion of the particles, a convection-diffusion equation is constructed based on the particle volume fraction, where the convection-diffusion equation is expressed as follows:

$$\frac{\partial ϕ}{\partial t} + ∇ \cdot ( ϕ u ) = ∇ \cdot ( {D}_{ϕ} ∇ ϕ )$$

where φ represents the scalar field (for example, a concentration of a substance, a phase field, and the like),

$$\frac{\partial ϕ}{\partial t}$$

represents a change rate of the scalar field φ (for example, a concentration or other physical quantities) with respect to time; U represents the velocity field; ∇ represents a divergence operator, which describes a diffusion phenomenon; Do represents a diffusion coefficient, which describes a diffusion rate or a diffusion capability of the scalar field φ.

In addition, to more accurately simulate interactions between the solid particles and the fluid, a solid-fluid slip model is adopted to establish a velocity relationship between the solid particles and an internal flow. For the solid-fluid slip model, it is assumed that the solid particles slip within the fluid, and a linear relationship between the velocity of the solid particles and the velocity of the fluid is expressed as follows:

$${u}_{s} = α {u}_{f}$$

where μₛ represents the velocity of the solid particles, u_{f} represents the velocity of the fluid, and a represents a slip coefficient.
(5) In a single-phase flow and pipeline nonlinear coupled vibration governing equation based on the Euler-Bernoulli beam, a uniform flow velocity and a constant density are determined as fluid parameters. The single-phase flow and pipeline nonlinear coupled vibration governing equation based on the Euler-Bernoulli beam is derived according to axial and radial dynamic balance principles and Hamilton's principle of virtual work.

Assuming that the pipeline is a slender elastic beam, a vibration behavior of the pipeline may be described by a vibration governing equation for a beam, that is, a pipeline vibration model of the beam is constructed, where a vibration displacement equation for the beam in the pipeline vibration model of the beam is expressed as follows:

$$E I \frac{{\partial }^{4} w}{\partial {z}^{4}} + {ρ}_{A} \frac{{\partial }^{2} w}{\partial {t}^{2}} = {F}_{vib} ( z , t ) + {F}_{Cor} + {F}_{Cen}$$

where E represents an elastic modulus, I represents an area moment of inertia; EI represents bending stiffness of the beam;

$$\frac{{\partial }^{4} w}{\partial {z}^{4}}$$

represents a variation of deflection (w) of the beam with a beam length (z); ρ_{A} represents a linear density;

$$\frac{{\partial }^{2} w}{\partial {t}^{2}}$$

represents a second derivative of the deflection (w) with respect to time (t), that is, an acceleration of the beam; F_{vib}(z,t) represents a distributed load along a pipeline length; F_{Cor} represents a Coriolis force, that is, an inertial force due to rotation; and F_{Cen} represents a centrifugal force, and describes a centrifugal effect experienced by an object in a rotating reference frame.

The Coriolis force and the centrifugal force described above are calculated based on a unified element which is obtained by performing linear superposition on a fluid element and a particle element. The motion of the fluid and the particles may cause pipeline vibration and instability, and the Coriolis force and the centrifugal force are expressed as follows:

$${F}_{Cor} = - 2 m ( Ω \times v )$$

$${F}_{Cen} = m Ω \times ( Ω \times r )$$

where F_{Cor} represents the Coriolis force; F_{Cen} represents the centrifugal force; M represents mass; Ω represents a rotational angular velocity; and V represents a velocity.

Assuming that a forced vibration is a simple harmonic vibration, the distributed load along the pipeline length in the above equations are expressed as:

$${F}_{v i b} ( z , t ) = A sin ( ω t ) sin ( \frac{π z}{L} )$$

where F_{vib}(z,t) represents the distributed load along the pipeline length; A represents a cross sectional area of the pipeline; w) represents a vibration frequency; t represents time; z represents pipeline length coordinates; and L represents a total length of the pipeline.

In the present disclosure, upper and lower boundary conditions of the pipeline are further described, where both an upper boundary and a lower boundary adopt rotational elastic support and horizontal elastic support. In an embodiment, the upper and lower boundary conditions may be expressed as follows.

For the upper boundary z=0, the deflection w(0,t)=0 (the horizontal elastic support), and the acceleration of the beam:

$$\frac{\partial w}{\partial z} ( 0 , t ) = 0 ( no rotation ) .$$

For the lower boundary z=L, the deflection w(L,t)=0 (the horizontal elastic support), and the acceleration of the beam:

$$\frac{\partial w}{\partial z} ( L , t ) = 0 ( no rotation ) .$$

In this process, instead of detailed tracking of particle motion, the pseudo-fluid model is constructed based on the effective density and the effective viscosity. Compared with conventional algorithms, computational workload is reduced, and thereby computational efficiency is improved.

In step S103, numerical simulation is performed on the deep-sea mining pipeline by using a pseudo-fluid model, to obtain a deep-sea mining numerical simulation result, where the deep-sea mining numerical simulation result includes a pressure distribution, a velocity field, a particle concentration distribution, an effective density, and an effective viscosity.

In an embodiment, step S103 includes steps S1031 and S1032. In step S1031, the Navier-Stokes equation, the convection-diffusion equation, and the vibration governing equation for the beam are discretized to obtain discrete equations. In step S1032, the discrete equations are solved through a high-precision iterative method to obtain the deep-sea mining numerical simulation result.

Most physical phenomena are mathematically described by continuous partial differential equations (PDEs), such as the Navier-Stokes equation in fluid dynamics. Such continuous equations fail to be directly processed by a computer, necessitating being converted into discrete forms for numerical solution. Advantages of discretization include the following (1) to (4). (1) Computational feasibility: by dividing continuous problem domains (such as time and space) into a finite number of discrete elements or points, an issue may be addressed by using limited computational resources. After discretization, states of all discrete elements are progressively solved by a computer with algorithms, thereby approximately simulating behaviors of an entire physical system. (2) Algorithmically realizability: discretization enables issues to be solved by applying various established numerical algorithms, such as a finite difference method (FDM), a finite volume method (FVM), and a finite element method (FEM). Through these algorithms, an equation set obtained through discretization is effectively processed and numerical solutions are computed. (3) Accuracy and stability: during discretization, it is required to determine appropriate discretization step sizes and algorithms, and thus the computational accuracy and stability of the numerical solutions are ensured. Inappropriate discretization may cause numerical solutions deviated from true solutions or numerical instability. (4) Enabling verifiability: the discretized numerical model is validated by being compared with experimental data, and model parameters are adjusted based on experimental or field data, thus improving accuracy and applicability of the model.

The step S1031 of discretizing the Navier-Stokes equation, the convection-diffusion equation, and the vibration governing equation for the beam to obtain discrete equations may include:
performing discretization by using the finite difference method (FDM) or the finite volume method (FVM) as follows.
(1) Discretization of the time derivative term:

$$\frac{\partial u}{\partial t} \approx \frac{{u}^{n + 1} - {u}^{n}}{Δ t}$$

where

$$\frac{\partial u}{\partial t}$$

represents a change rate of the velocity field with respect to time; uⁿ⁺¹ represents a value of the velocity field at a next time step (a time instant n+1); uⁿ represents a known value of the velocity field at a current time step (a time instant n); and Δt represents a step size for time discretization, that is, a time interval from the current time step (n) to the next time step (n+1).

In the numerical simulation, the discretization for the time derivative term is a process of converting a continuous time variable into discrete steps, with a purpose of simulating and solving on a computer. The discretization for the time derivative term is a critical step in solving dynamic (time-dependent) issues, and in particular in solving partial differential equations (such as the Navier-Stokes equation in fluid dynamics).
(2) Discretization of a convective term

$$u \cdot ∇ u \approx {u}^{n} \cdot ( \frac{{u}_{i + 1 , j}^{n} - {u}_{i - 1 , j}^{n}}{2 Δ x} , \frac{{u}_{i , j + 1}^{n} - {u}_{i , j - 1}^{n}}{2 Δ y} , \frac{{u}_{i , j , k + 1}^{n} - {u}_{i , j , k - 1}^{n}}{2 Δ z} )$$

where u represents the velocity field; uⁿ represents the known value of the velocity field at the current time step (a time instant n); ∇u represents a gradient of the velocity field, that is, a change rate of a velocity in space;

$${u}_{i + 1 , j}^{n} , {u}_{i - 1 , j}^{n}$$

represents values of the velocity field of adjacent points immediately before and after a current point in an x direction;

$${u}_{i , j + 1}^{n} , {u}_{i , j - 1}^{n}$$

represents values of the velocity field of adjacent points immediately before and after the current point in a y direction;

$${u}_{i , j , k + 1}^{n} , {u}_{i , j , k - 1}^{n}$$

represents values of the velocity field of adjacent points immediately before and after the current point in a z direction; and Δx, Δy, Δz represents discrete spacing in the x direction, the y direction, and the z direction of the grid.

In the numerical simulation, the discretization for the convective term is a process of converting a continuous form in a convection equation (which represents a transportation process of matter, energy, and the like) into a discrete form in the numerical simulation, thus facilitating solution on a computer.
(3) Discretization of a viscosity term

$$∇ \cdot [ {μ}_{eff} ( ∇ u + {( ∇ u )}^{T} ) ] \approx {\sum }_{i , j} \frac{\partial }{\partial {x}_{i}} ( {μ}_{eff} \frac{\partial {u}_{j}}{\partial {x}_{i}} )$$

where ∇ represents a divergence degree of a vector field at a given point, which acts on a viscous stress term; μ_{eff} represents an effective viscosity; ∇u represents the velocity gradient, that is, a change rate of the velocity field in all directions;

$$\frac{\partial }{\partial {x}_{i}}$$

represents a spatial derivative in the i direction; and

$$\frac{\partial {u}_{j}}{\partial {x}_{i}}$$

represents a j-th component of the velocity field.

In the numerical simulation, the discretization of the viscosity term involves a process of converting a term describing viscous effects in the fluid dynamics equation (such as the viscous dissipation term in the Navier-Stokes equation) into a discrete format that is executable by a computer.
(4) Discretization of a vibration governing equation for the beam

$$EI \frac{{\partial }^{4} w}{\partial {z}^{4}} + {ρ}_{A} \frac{{\partial }^{2} w}{\partial {t}^{2}} \approx A sin ( ω t ) sin ( \frac{π z}{L} )$$

where E represents the elastic modulus, I represents the area moment of inertia; EI represents the bending stiffness of the beam;

$$\frac{{\partial }^{4} w}{\partial {z}^{4}}$$

represents the variation of the deflection (w) of the beam with the beam length (z); ρ_{A} represents the linear density;

$$\frac{{\partial }^{2} w}{\partial {t}^{2}}$$

represents the second derivative of the deflection (w) with respect to time (t), that is, the acceleration of the beam; A represents a cross sectional area of the pipeline; w) represents a vibration frequency; t represents time; z represents the pipeline length coordinates; and L represents the total length of the pipeline.

The above-described

$$\frac{{\partial }^{4} w}{\partial {z}^{4}}$$

may be discretized through the central difference method:

$$\frac{{\partial }^{4} w}{\partial {z}^{4}} \approx \frac{{w}_{i + 2} - 4 {w}_{i + 1} + 6 {w}_{i} - 4 {w}_{i - 1} + {w}_{i - 2}}{Δ {z}^{4}}$$

where

$$\frac{{\partial }^{4} w}{\partial {z}^{4}}$$

represents a fourth derivative of w with respect to z, that is, a change rate of curvature; wᵢ represents a variable w at an i-th grid point, that is, deflection (displacement) of the beam at the i-th grid point; Δz represents a spatial step size of the grid in the z direction, that is, a distance between adjacent grid points.

In above-described step S1032, solving the discrete equations through a high-precision iterative method to obtain the deep-sea mining numerical simulation result includes steps (1) to (5).

In step (1), a predicted velocity field is obtained based on the discrete equations, the effective density, the effective viscosity, and a velocity field formula, where the predicted velocity field is expressed as follows:

$$u = {u}^{n} - Δ t ( {u}^{n} \cdot ∇ {u}^{n} + \frac{∇ {p}^{n}}{{ρ}_{eff}} - \frac{∇ \cdot [ {μ}_{eff} ( ∇ {u}^{n} + {( ∇ {u}^{n} )}^{T} ) ]}{{ρ}_{eff}} ) + Δ {tF}_{vib}$$

where u represents the velocity field; uⁿ represents a value of the velocity field at a previous time step (that is, a time instant n); Δt represents a time step size; uⁿ·∇uⁿ represents a convective term of the velocity field, that is, a variation of the velocity of the fluid with space during a motion of the fluid; ρ_{eff} represents the effective density; ∇pⁿ represents a pressure gradient term; μ_{eff} represents the effective viscosity; ∇·[μ_{eff}(∇uⁿ+(∇uⁿ)^{T})] represents a viscous force term; and F_{vib} represents an impact of an external vibrational force or another external force applied to the fluid on the velocity field.

In step (2), the predicted velocity field is substituted into a continuity equation to obtain a pressure correction equation, and the pressure correction equation is expressed as follows:

$${A}_{p} {p}^{′} = b$$

where Aₚ is a pressure correction coefficient matrix; p′ represents a pressure correction value; and b is a source term vector.

In step (3), the velocity field, the pressure field, and a vibration displacement of the beam are updated based on the pressure correction equation.

First, the velocity field uⁿ⁺¹ is updated and corrected by:

$${u}^{n + 1} = {u}^{*} \frac{Δ t}{{ρ}_{eff}} ∇ {p}^{n + 1}$$

where uⁿ⁺¹ represents the velocity field at a next time step (n+1), that is, the updated fluid velocity; u* represents the predicted velocity field, which is typically an intermediate velocity field obtained by computation of a velocity equation without considering the pressure term; Δt represents the time step size; ρ_{eff} represents the effective density; ∇pⁿ⁺¹ represents a pressure gradient at a next time step, that is, a variation of the pressure with a spatial position.

Next, the pressure field pⁿ⁺¹ is updated by

$${p}^{n + 1} = {p}^{n} + {α}_{p} {p}^{′}$$

where pⁿ⁺¹ represents a pressure field at a next time step (n+1); pⁿ represents a pressure field at a current time step (n); αₚ represents a relaxation factor; and p′ represents the pressure correction value.

Finally, a vibration displacement wⁿ⁺¹ of the beam is updated:

$${ρ}_{A} \frac{{\partial }^{2} {w}^{n + 1}}{\partial {t}^{2}} = A sin ( ω t ) sin ( \frac{π z}{L} ) - EI \frac{{\partial }^{4} {w}^{n + 1}}{\partial {z}^{4}}$$

where ρ_{A} represents the linear density;

$$\frac{{\partial }^{2} {w}^{n + 1}}{\partial {t}^{2}}$$

represents an acceleration of the beam at a next time step (n+1); EI represents the bending stiffness of the beam;

$$\frac{{\partial }^{4} {w}^{n + 1}}{\partial {z}^{4}}$$

represents the variation of the deflection (w) of the beam with the beam length (z) at the next time step (n+1); A represents the cross-sectional area of the pipeline; ω represents the vibration frequency; t represents time; z represents the pipeline length coordinates; and L represents the total length of the pipeline.

In step (4), the effective density and the effective viscosity are updated based on the updated velocity field and particle concentration distributions at different time steps.

The update formulas for updating the effective density and the effective viscosity are expressed as follows:

$${μ}_{eff} = {{μ}_{f} ( 1 - \frac{ϕ}{{ϕ}_{m}} )}^{- 2.5 {ϕ}_{m}}$$

$${ρ}_{eff} = {ϕρ}_{s} + ( 1 - ϕ ) {ρ}_{f}$$

where μ_{eff} represents the effective viscosity; μ_{f} represents the viscosity of the base fluid; φ represents the particle volume fraction; φₘ represents the maximum particle volume fraction of the solid particles; ρ_{eff} represents the effective density; ρₛ represents the density of the solid particles; and ρ_{f} represents the density of the fluid.

It should be noted that in the numerical simulation, and in particular a situation involving a pseudo-fluid model of a solid-fluid two-phase flow, an effective density and an effective viscosity are core parameters which are used to describe overall fluid dynamics behaviors of a mixture. These parameters have a significant impact on other variables in the simulation, such as the velocity field, the pressure field, and a structural response (for example, the vibration displacement of the beam).

Therefore, for optimization of parameters in the embodiment of the present disclosure, the effective density and the effective viscosity are updated. The update of the effective density and the effective viscosity is based on experimental data. The specific process may include: measuring a density and a viscosity of a solid-fluid mixture by means of an experimental apparatus to determine a standard effective density and a standard effective viscosity; calculating an error by comparing the effective density with the standard effective density and comparing the effective viscosity with the standard effective viscosity; continuing, in response to the error being greater than a predetermined value, to the process of updating the effective density and the effective viscosity based on the updated velocity field and particle concentration distributions at different time steps. Through a preliminary numerical simulation, the effective density and the effective viscosity are adjusted to enable the simulation result to be consistent with the experimental data, and thereby correction of the effective parameter is implemented.

In the embodiment of the present disclosure, the effective parameters of the pseudo-fluid are accurately determined through a method combining an experiment and a numerical simulation. Through experimental measurement and simulation correction, the accuracy and reliability of the model parameters are ensured.

In step (5), the operations from obtaining the predicted velocity field to updating the effective density and the effective viscosity are repeatedly updated until variations of the velocity field and pressure field satisfy a convergence criterion, to obtain the deep-sea mining numerical simulation result.

The equations of the variations satisfying the convergence criterion is expressed as follows:

$$‖ {u}^{n + 1} - {u}^{n} ‖ < ϵ$$

$$‖ {p}^{n + 1} - {P}^{n} ‖ < ϵ$$

where uⁿ⁺¹ represents the velocity field at the next time step (n+1); uⁿ represents the velocity field at the current time step (n); pⁿ⁺¹ represents the pressure field at the next time step (n+1); pⁿ represents the pressure field at the current time step (n); and E is a convergence error.

In this process, computational time of the pseudo-fluid model-based numerical simulation method is significantly lower than that of conventional methods, and thus the pseudo-fluid model-based numerical simulation method is applicable for a large-scale and long-term simulation. By comparing computational efficiency, the practical value of the pseudo-fluid model in engineering applications is demonstrated.

In addition, in the embodiment of this disclosure, optimization of operating parameters may be performed, and includes the following (1) to (2):

### (1) Pressure Drop Calculation:

By simulating pressure drops under different operational conditions, an optimal lifting velocity and particle concentration are determined. In a case that flow velocities at inlets of different deep-sea mining pipelines are represented by uᵢₙ and particle concentrations at the inlets of the different deep-sea mining pipelines are represented by φᵢₙ, the pressure drop is represented by Δp, an operational condition with the lowest pressure drop is selected.

A relationship among the flow velocity, the particle concentration, and the pressure drop is described in detail as follows.

A higher flow velocity causes a greater resistance for the fluid to pass through the pipeline or the system, and then causes a higher pressure drop. At a high flow velocity, particle motion may also be affected, and a stronger convection may occur, potentially reducing settling time for particles.

A higher particle concentration increases the viscosity and density of a fluid, and increases the flow resistance of the fluid. Especially at a high particle concentration, interactions between the particles and the fluid, as well as interactions between particles, cause a higher pressure drop. A high particle concentration may cause a blockage or increased friction, thereby affecting fluidity and pressure distribution.

The pressure drop refers to a pressure loss of a fluid caused by factors such as friction and flow resistance during a flow process. A high flow velocity and a high particle concentration generally indicate a high pressure drop. In a simulation process, pressure drops under different operational conditions are used to evaluate energy efficiency of the system and a transportation capacity of the fluid. The optimal operating conditions are typically determined to minimize the pressure drop while maintaining appropriate particle concentrations and meeting flow rate requirements.

### (2) Flow Stability Analysis:

Impacts of external factors such as ocean currents and waves on the flow stability within a lifting pipeline are analyzed to optimize pipeline design. Flow states under different ocean current velocities and wave conditions are simulated to ensure system stability under various external disturbances.

In an embodiment of the present disclosure, after obtaining the deep-sea mining numerical simulation result, the deep-sea mining numerical simulation result is analyzed, and the process includes following (1) to (3).

### (1) Pressure Distribution Analysis

A map of pressure distribution within the lifting pipeline is displayed, and pressure drops under different operational conditions are analyzed. By comparing pressure distributions under different flow velocities and particle concentrations, optimal operating parameters are determined.

### (2) Velocity Field Analysis

A velocity field distribution map is displayed and motion behaviors of particles in the lifting pipeline are analyzed. Based on visualization of the velocity field, potential regions of flow instability are identified.

Specific process may include velocity field display and analysis, determination of regions of flow instability and determination of regions of potential flow instability.

Velocity field display and analysis: by generating velocity field distribution diagrams through simulation, flow behaviors of the particles and the fluid within the lifting pipeline is clearly displayed. This visualization manner enables researchers to intuitively analyze motion trajectories of the fluid and the particles within the pipeline.

Determination of unstable regions: in the velocity field map, regions of flow instability generally exhibit sudden changes in velocity or irregular flow. These regions of flow instability may exhibit obvious phenomena such as flow separation, vortices, or backflow. These regions can be identified based on a flow line map and a velocity vector diagram.

Determination of regions of potential flow instability: through visualization of the velocity field, researchers can identify regions of potential flow instability. These regions are generally positions where the flow velocity changes drastically, such as pipeline corners, diameter changing sections, or regions affected by external factors.

### (3) Particle Concentration Distribution Analysis

A particle concentration distribution map is displayed for identification of potential blockage regions. By analyzing a particle concentration distribution, the pipeline design and the operating parameters are optimized to prevent blockages.

Specific process may include: analyzing the particle concentration distribution map and optimizing the pipeline design and the operating parameters.

For the analyzing the particle concentration distribution map, by displaying and analyzing the particle concentration distribution, potential particle accumulation regions within the flow system are identified. These regions cause pipeline blockages, increases system resistance, or cause pressure drops.

For a relationship between the particle concentration distribution and the pipeline design and the operating parameters, the particle concentration distribution is closely related to the pipeline design (such as a pipeline diameter and a flow channel structure) and the operating parameters (such as the flow velocity and the pressure). Nonuniform particle concentration distribution may be caused by improper pipeline design (for example, sudden drastic changes in diameter) or improper operating parameter settings (for example, the flow velocity being excessively low or excessively high).

For optimizing the pipeline design and the operating parameters, by analyzing the particle concentration distribution, researchers optimize the pipeline design and the operating parameters to realize the optimization objective of reducing particle accumulation and preventing blockages. Specific optimization measures may include: adjusting the flow velocity or the pressure to prevent particle deposition; modifying the pipeline structure or pipeline materials to enable the particles to be distributed more uniformly within the fluid; and
introducing a special mixing apparatus or design to maintain uniform particle flow.

As can be seen, in the embodiments of the present disclosure, calculation of a multiphase flow is simplified by treating solid particles as a pseudo-fluid. By introducing an effective density and an effective viscosity, tracking of particle motion details is reduced, and computational efficiency of an entire deep-sea mining numerical simulation is improved.

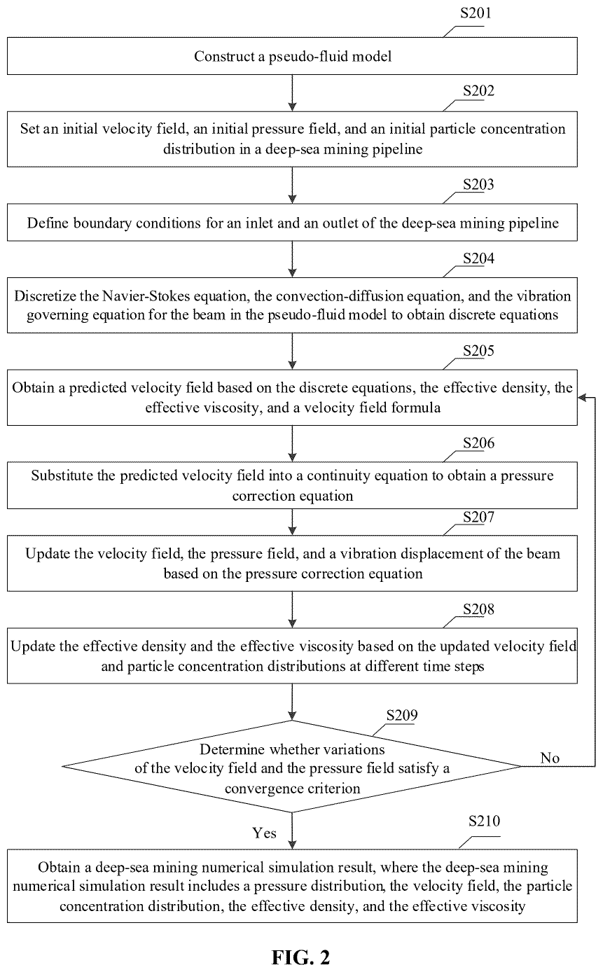

To make the method according to the embodiments of the present disclosure clear and comprehensible, a specific embodiment of the method is illustrated below in conjunction with FIG. 2.

As shown in FIG. 2, the embodiment may include the following steps S201 to S210.

In step S201, a pseudo-fluid model is constructed.

In the present disclosure, solid particles are treated as a pseudo-fluid. With introducing an effective density and an effective viscosity in the pseudo-fluid model, tracking of particle motion details is reduced, and computational efficiency of an entire deep-sea mining numerical simulation is improved.

As shown in a schematic diagram of a pseudo-fluid model in FIG. 3, the pseudo-fluid model is illustrated as follows. Solid Particles, denoted by small dots in FIG. 3, are uniformly dispersed in the fluid, with a particle density of ρₛ and a particle volume fraction of φ. The fluid, denoted by a background color in FIG. 3, fills an entire pipeline, with a density of ρ_{f}. The Pseudo-fluid with the effective density and the effective viscosity characterizes an overall property of a mixture. Specific equations for the effective density and the effective viscosity are shown in the above-described embodiments and will not be repeated here.

In the embodiment of the present disclosure, constructing a pseudo-fluid model may include: (1) obtaining an effective density; (2) obtaining an effective viscosity; (3) determining a Navier-Stokes equation for the pseudo-fluid model based on the effective density and the effective viscosity; (4) constructing a convection-diffusion equations based on a particle volume fraction; and (5) constructing a vibration governing equation for a beam.

Specific equations for constructing the pseudo-fluid model are known from the above-described embodiments and are not repeated here.

The vibration governing equation for the beam expresses a pipeline vibration model based on the Euler-Bernoulli beam, as shown in FIG. 4, which includes a pipeline, a vibration displacement, and boundary conditions. In the FIG. 4, L represents a pipeline length, and F represents a distributed load. Both L and F are indicated by arrows to show the distributed load along the pipeline length.

In step S202, an initial velocity field, an initial pressure field, and an initial particle concentration distribution in a deep-sea mining pipeline are set.

In the embodiment of the present disclosure, to ensure convergence of the simulation and consistency of the simulation with physical laws during a subsequent numerical simulation, it is required to preset the initial velocity field, the initial pressure field, and the initial particle concentration distribution within the deep-sea mining pipeline. In an embodiment, the initial velocity field is set to u₀; the initial pressure field is set to p₀; and the initial particle concentration is set to φ₀.

In step S203, boundary conditions at an inlet and an outlet of the deep-sea mining pipeline are defined.

In the embodiment of the present disclosure, for determining variation rules of variables or derivatives of the variables at boundaries of a solution region, the boundary conditions at the inlet and the outlet of the deep-sea mining pipeline are defined. In an embodiment, the inlet velocity of the deep-sea mining pipeline is set to a fixed velocity uᵢₙ, an outlet pressure of the deep-sea mining pipeline is set to a fixed pressure pₒᵤₜ, and an inlet particle concentration of the deep-sea mining pipeline is set to φᵢₙ.

In step S204, the Navier-Stokes equation, the convection-diffusion equation, and the vibration governing equation for the beam in the pseudo-fluid model are discretized to obtain discrete equations.

Such continuous equations fail to be directly processed by a computer, and thus are required to be converted into discrete forms for numerical solving. The specific discretization process includes: (1) discretization of the time derivative term; (2) discretization of a convective term; (3) discretization of a viscosity term; and (4) discretization of a vibration equation for the beam. A specific discretization process is shown in the above-described embodiments and will not be repeated here.

In step S205, a predicted velocity field is obtained based on the discrete equations, the effective density, the effective viscosity, and a velocity field formula.

After obtaining the discrete equations, the discrete equations are solved by using a high-precision iterative method to obtain a deep-sea mining numerical simulation result. First, the predicted velocity field is obtained based on the discrete equations, the effective density, the effective viscosity, and the velocity field formula. A specific process for obtaining the predicted velocity field is shown in the above-described embodiment and will not be repeated here.

In step S206, the predicted velocity field is substituted into a continuity equation to obtain a pressure correction equation.

To update and correct the velocity field, a pressure field, and a vibration displacement of the beam in subsequent steps, the pressure correction equation is obtained beforehand. A specific process for obtaining the pressure correction equation is shown in the above-described embodiment and will not be repeated here.

In step S207, the velocity field, the pressure field, and the vibration displacement of the beam are updated based on the pressure correction equation.

First, the velocity field uⁿ⁺¹ is updated and corrected, then the pressure field pⁿ⁺¹ is updated, and finally the vibration displacement wⁿ⁺¹ of the beam is updated.

In step S208, the effective density and the effective viscosity are updated based on the updated velocity field and particle concentration distributions at different time steps.

In the numerical simulation, and in particular a situation involving a solid-fluid two-phase flow such as a pseudo-fluid model, an effective density and an effective viscosity are core parameters which are used to describe overall fluid dynamics behaviors of a mixture. These parameters have a significant impact on other variables in the simulation, such as the velocity field, the pressure field, and a structural response (for example, the vibration displacement of the beam). Therefore, the effective density and the effective viscosity are optimized, that is, the effective density and the effective viscosity are updated. Specific updating is based on a method combining an experiment and a numerical simulation to accurately determine the effective parameters of the pseudo-fluid. Through experimental measurement and simulation correction, the accuracy and reliability of the model parameters are ensured. A specific determination process is shown in the above-described embodiment and will not be repeated here.

In step S209, it is determined whether variations of the velocity field and the pressure field satisfy a convergence criterion.

During the deep-sea mining numerical simulation, it is required to determine whether the variations of the velocity field and the pressure field satisfy a convergence criterion. If the convergence criterion is satisfied, the current numerical simulation result satisfies requirements, and the numerical simulation process may be terminated, that is, step S210 is to be performed; and if the convergence criterion is not satisfied, the current numerical simulation result does not satisfy the requirements, and the method goes to the numerical simulation process, that is, step S205 is to be performed.

In step S210, if the criterion is satisfied, the deep-sea mining numerical simulation result is obtained. The deep-sea mining numerical simulation result includes a pressure distribution, the velocity field, the particle concentration distribution, the effective density, and the effective viscosity.

The pseudo-fluid model-based numerical simulation method for deep-sea mining is provided according to the embodiment. By applying the pseudo-fluid model to numerical simulation for deep-sea mining, computational process is significantly simplified, simulation efficiency is improved, and key issues such as the calculation of the pressure drop, determination of the particle distribution, and analysis of the flow stability are addressed. Additionally, by optimizing operating parameters such as the lifting velocity and the particle concentration, stable operation for the system under various operating conditions is ensured. By optimizing operating parameters, equipment maintenance costs are reduced, and economic benefits are improved. By reducing the pressure drop and energy consumption, operational costs are lowered, and economic benefits are improved.

Referring to FIG. 5, a pseudo-fluid model-based numerical simulation apparatus 500 for deep-sea mining is provided according to an embodiment of the present disclosure. The apparatus includes a setting unit 501, a definition unit 502, and a numerical simulation unit 503.

The setting unit 501 is configured to set an initial velocity field, an initial pressure field, and an initial particle concentration distribution in a pipeline.

The definition unit 502 is configured to define boundary conditions at an inlet and an outlet of the pipeline.

The numerical simulation unit 503 is configured to perform numerical simulation on the deep-sea mining pipeline by using a pseudo-fluid model, to obtain a deep-sea mining numerical simulation result, where the deep-sea mining numerical simulation result includes a pressure distribution, a velocity field, a particle concentration distribution, an effective density, and an effective viscosity.

In an embodiment, the apparatus 500 further includes an obtaining unit, a determination unit and a construction unit.

The obtaining unit is configured to perform a weighted average calculation on a density of solid particles and a density of a fluid according to a particle volume fraction to obtain the effective density, and obtain the effective viscosity based on the particle volume fraction and a viscosity of a base fluid.

The determination unit, configured to determine a Navier-Stokes equation for the pseudo-fluid model based on the effective density and the effective viscosity:

$${ρ}_{eff} ( \frac{\partial u}{\partial t} + u \cdot ∇ u ) = - ∇ p + ∇ \cdot [ {μ}_{eff} ( ∇ u + {( ∇ u )}^{T} ) ] + {ρ}_{eff} g + {F}_{v i b}$$

where, ρ_{eff} represents an effective density, u represents a velocity field; ∇ represents divergence or contraction of a vector field in space; t represents time, and

$$\frac{\partial u}{\partial t}$$

represents a change rate of the velocity field with respect to time; p represents a pressure field; μ_{eff} represents an effective viscosity; g represents gravity; and F_{vib} represents an impact of an external vibrational force applied to the fluid on the velocity field;
The construction unit is configured to construct a convection-diffusion equation based on the particle volume fraction, where the convection-diffusion equation is expressed as

$$\frac{\partial ϕ}{\partial t} + ∇ \cdot ( ϕ u ) = ∇ \cdot ( {D}_{ϕ} ∇ ϕ )$$

where φ represents a scalar field;

$$\frac{\partial θ}{\partial t}$$

represents a change rate of the scalar field φ with respect to time; u represents the velocity field; ∇ represents a divergence operator; and D_{φ} represents a diffusion coefficient, which describes a diffusivity of the scalar field φ.

The construction unit is further configured to construct a pipeline vibration model of a beam, where a vibration displacement equation for the beam in the pipeline vibration model of the beam is expressed as

$$EI \frac{{\partial }^{4} w}{\partial {z}^{4}} + {ρ}_{A} \frac{{\partial }^{2} w}{\partial {t}^{2}} = {F}_{vib} ( z , t ) + {F}_{Cor} + {F}_{Cen}$$

where E represents an elastic modulus; I represents an area moment of inertia; EI represents bending stiffness of the beam;

$$\frac{{\partial }^{4} w}{\partial {z}^{4}}$$

represents a variation of deflection of the beam with a beam length; ρ_{A} represents a linear density;

$$\frac{{\partial }^{2} w}{\partial {t}^{2}}$$

represents a second derivative of the deflection with respect to time, that is, an acceleration of the beam; F_{vib}(z,t) represents a distributed load along a pipeline length; F_{Cor} represents a Coriolis force; and F_{Cen} represents a centrifugal force.

In an embodiment, the numerical simulation unit 503 further includes a conversion subunit, and a solution subunit.

The conversion subunit is configured to discretize the Navier-Stokes equation, the convection-diffusion equation, and the vibration governing equation for the beam to obtain discrete equations.

The solution subunit is configured to solve the discrete equations by using a high-precision iterative method to obtain the deep-sea mining numerical simulation result.

In an embodiment, the solution subunit is further configured to:
obtain a predicted velocity field based on the discrete equations, the effective density, the effective viscosity, and a velocity field formula, where the predicted velocity field formula is expressed as follows:

$$u = {u}^{n} - Δ t ( {u}^{n} \cdot ∇ {u}^{n} + \frac{∇ {p}^{n}}{{ρ}_{eff}} - \frac{∇ \cdot [ {μ}_{eff} ( ∇ {u}^{n} + {( ∇ {u}^{n} )}^{T} ) ]}{{ρ}_{eff}} ) + Δ {tF}_{v i b}$$

where u represents the velocity field; uⁿ represents a value of the velocity field at a previous time step; Δt represents a time step size; uⁿ·∇uⁿ represents a convective term of the velocity field; ρ_{eff} represents the effective density; ∇pⁿ represents a pressure gradient term; μ_{eff} represents the effective viscosity; ∇·[μ_{eff}(∇uⁿ+(∇uⁿ)^{T})] represents a viscous force term; and F_{vib} represents an impact of an external vibrational force applied to the fluid on the velocity field;
substitute the predicted velocity field into a continuity equation to obtain a pressure correction equation, and the pressure correction equation is expressed as follows

$${A}_{p} {p}^{′} = b$$

where Aₚ is a pressure correction coefficient matrix; p′ represents a pressure correction value; and b represents a source term vector;
update the velocity field, the pressure field, and a vibration displacement of the beam based on the pressure correction equation;
update the effective density and the effective viscosity based on the updated velocity field and particle concentration distributions at different time steps; and
repeatedly perform the operations from obtaining the predicted velocity field to updating the effective density and the effective viscosity until variations of the velocity field and the pressure field satisfy a convergence criterion, to obtain the deep-sea mining numerical simulation result.

In an embodiment, for updating the effective density and the effective viscosity based on the updated velocity field and particle concentration distributions at different time steps, the solution subunit is configured to:
measure a density and a viscosity of a solid-fluid mixture by means of an experimental apparatus to determine a standard effective density and a standard effective viscosity;
calculate an error by comparing the effective density with the standard effective density and comparing the effective viscosity with the standard effective viscosity; and
continue, in response to the error being greater than a predetermined value, to the process of updating the effective density and the effective viscosity based on the updated velocity field and particle concentration distributions at different time steps.

In an embodiment, the definition unit 502 is further configured to:
define a fixed flow velocity and a fixed particle concentration for the inlet of the deep-sea mining pipeline; and
define a fixed pressure for the outlet of the deep-sea mining pipeline.

It should be noted that an implementation and an effect achieved of the pseudo-fluid model-based numerical simulation apparatus 500 for deep-sea mining may be referred to relevant descriptions in the pseudo-fluid model-based numerical simulation method provided in FIG. 1 and FIG. 2 described above, and will not be repeated here.

An electronic device 600 is further provided according to an embodiment of the present disclosure. As shown in FIG. 6, the electronic device 600 includes a memory 601 and a processor 602.

The memory 601 stores a computer program.

The processor 602 is configured to execute the computer program to perform the method shown in FIG. 1 or FIG. 2.

A computer-readable storage medium is further provided according to an embodiment of the present disclosure. The computer-readable storage medium stores a computer program. The computer program is executed to perform the pseudo-fluid model-based numerical simulation method shown in FIG. 1 or FIG. 2.

From the above embodiments, those skilled in the art can clearly appreciate that all or a part of steps in the method according to the above embodiments may be implemented by means of software and a general hardware platform. Based on such understanding, technical solutions of the present disclosure may be embodied as a software product. The computer software product may be stored in a storage medium, such as a read-only memory (ROM)/RAM, a magnetic disc, or an optical disk, and the computer software product includes multiple instructions for enabling a computer device (which may be a personal computer, a server, or a network communication device such as a router) to perform the methods described in various embodiments or some parts of the embodiments of the present disclosure.

The embodiments in this specification are described in a progressive manner. Various embodiments may refer to each other for the same or similar parts, and each embodiment focuses on the difference from other embodiments. The device embodiments are essentially similar to the method embodiments, and therefore are described in brief Reference may be made to the description of the method embodiments for relevant details of the device embodiments. The apparatus embodiments described above are only illustrative. The modules described as separate components may be or may not be separated physically, and the components shown as modules may be or may not be physical modules, that is, the components may be arranged at the same position or may be distributed in multiple network units. Some or all modules may be selected according to actual requirements to implement the solutions in the embodiments. Those skilled in the art can understand and implement the solution without any creative effort.

The foregoing descriptions are only exemplary embodiments of the present disclosure, and are not intended to limit the protection scope of the present disclosure.

1. A pseudo-fluid model-based numerical simulation method for marine mining, comprising:
setting, by a processor, an initial velocity field, an initial pressure field, and an initial particle concentration distribution in a marine mining pipeline;
defining, by the processor, boundary conditions at an inlet and an outlet of the marine mining pipeline; and
performing, by the processor, numerical simulation on the marine mining pipeline by using a pseudo-fluid model to obtain a-deep-sea marine mining numerical simulation result, wherein the marine mining numerical simulation result comprises a pressure distribution, a velocity field, a particle concentration distribution, an effective density, and an effective viscosity; the pseudo-fluid model involves a Navier-Stokes equation, a convection-diffusion equation and a vibration governing equation for a beam, the Navier-Stokes equation correlates the effective density and the effective viscosity, the effective density refers to a weighted average of a density of solid particles and a density of a fluid based on a particle volume fraction, the effective viscosity depends on the particle volume fraction and a viscosity of a base fluid, the convection-diffusion equation is obtained based on the particle volume fraction, and the vibration governing equation for the beam is obtained based on a pipeline vibration model of the beam, and wherein
the performing, by the processor, numerical simulation on the marine mining pipeline by using a pseudo-fluid model to obtain a marine mining numerical simulation result comprises:
discretizing, by the processor, the Navier-Stokes equation, the convection-diffusion equation, and the vibration governing equation for the beam to obtain discrete equations; and
solving, by the processor, the discrete equations through an iterative method based on a predicted velocity field, a pressure gradient, a viscous force and an external vibrational force to obtain the marine mining numerical simulation result.

2. The pseudo-fluid model-based numerical simulation method according to claim 1, wherein the pseudo-fluid model is constructed based on
the Navier-Stokes equation, expressed as:
$${ρ}_{eff} ( \frac{\partial u}{\partial t} + u \cdot ∇ u ) = - ∇ p + ∇ \cdot [ {μ}_{eff} ( ∇ u + {( ∇ u )}^{T} ) ] + {ρ}_{eff} g + {F}_{v i b}$$
wherein ρ_{eff} represents the effective density, u represents the velocity field; ∇ represents divergence or contraction of a vector field in space; t represents time, and
$$\frac{\partial u}{\partial t}$$
at represents a change rate of the velocity field with respect to time; P represents the pressure field; μ_{eff} represents the effective viscosity; g represents gravity; and F_{vib} represents an impact of the external vibrational force applied to the fluid on the velocity field;
the convection-diffusion equation, expressed as
$$\frac{\partial ϕ}{\partial t} + ∇ \cdot ( ϕ u ) = ∇ \cdot ( {D}_{ϕ} ∇ ϕ )$$
wherein φ represents a scalar field;
$$\frac{\partial ϕ}{\partial t}$$
represents a change rate of the scalar field φ with respect to time; u represents the velocity field; ∇ represents a divergence operator; and Do represents a diffusion coefficient, which describes a diffusivity of the scalar field φ; and
the vibration governing equation for the beam in the pipeline vibration model of the beam expressed as
$$E I \frac{{\partial }^{4} w}{\partial {z}^{4}} + {ρ}_{A} \frac{{\partial }^{2} w}{\partial {t}^{2}} = {F}_{v i b} ( z , t ) + {F}_{C o r} + {F}_{C e n}$$
wherein E represents an elastic modulus; I represents an area moment of inertia; EI represents bending stiffness of the beam;
$$\frac{{\partial }^{4} w}{\partial {z}^{4}}$$
represents a variation of deflection of the beam with a beam length; ρ_{A} represents a linear density;
$$\frac{{\partial }^{2} w}{\partial {t}^{2}}$$
at represents a second derivative of the deflection with respect to time, that is, an acceleration of the beam; F_{vib}(z,t) represents a distributed load along a pipeline length; F_{Cor} represents a Coriolis force; and F_{Cen} represents a centrifugal force.

3. (canceled)

4. The pseudo-fluid model-based numerical simulation method according to claim 2, wherein the solving, by the processor, the discrete equations through an iterative method based on a predicted velocity field, a pressure gradient, a viscous force and an external vibrational force to obtain the marine mining numerical simulation result comprises:
obtaining, by the processor, the predicted velocity field based on the discrete equations, the effective density, the effective viscosity, and a velocity field formula, wherein the predicted velocity field is expressed as
$$u = {u}^{n} - Δ t ( {u}^{n} \cdot ∇ {u}^{n} + \frac{∇ {p}^{n}}{{ρ}_{eff}} - \frac{∇ \cdot [ {μ}_{eff} ( ∇ {u}^{n} + {( ∇ {u}^{n} )}^{T} ) ]}{{ρ}_{eff}} ) + Δ t {F}_{v i b}$$
wherein u represents the velocity field; uⁿ represents a value of the velocity field at a previous time step; Δt represents a time step size; uⁿ·∇uⁿ represents a convective term of the velocity field; ρ_{eff} represents the effective density; ∇pⁿ represents a pressure gradient term; μ_{eff} represents the effective viscosity; ∇·[μ_{eff}(∇uⁿ+(∇uⁿ)^{T})] represents a viscous force term; and F_{vib} represents the impact of the external vibrational force applied to the fluid on the velocity field;
substituting, by the processor, the predicted velocity field into a continuity equation to obtain a pressure correction equation, and the pressure correction equation is expressed as
$${A}_{p} {p}^{′} = b$$
wherein Aₚ represents a pressure correction coefficient matrix; p′ represents a pressure correction value; and b represents a source term vector;
updating, by the processor, the velocity field, the pressure field, and a vibration displacement of the beam based on the pressure correction equation;
updating, by the processor, the effective density and the effective viscosity based on the updated velocity field and particle concentration distributions at different time steps; and
repeatedly performing, by the processor, the operations from obtaining the predicted velocity field to updating the effective density and the effective viscosity until variations of the velocity field and the pressure field satisfy a convergence criterion, to obtain the marine mining numerical simulation result.

5. The pseudo-fluid model-based numerical simulation method according to claim 4, wherein the updating, by the processor, the effective density and the effective viscosity based on the updated velocity field and particle concentration distributions at different time steps comprises:
measuring, by the processor, a density and a viscosity of a solid-fluid mixture by means of an experimental apparatus to determine a standard effective density and a standard effective viscosity;
calculating, by the processor, an error by comparing the effective density with the standard effective density and comparing the effective viscosity with the standard effective viscosity; and
continuing, in response to the error being greater than a predetermined value, to the process of updating the effective density and the effective viscosity based on the updated velocity field and particle concentration distributions at different time steps by the processor.

6. The pseudo-fluid model-based numerical simulation method according to claim 1, wherein the defining, by the processor, boundary conditions at an inlet and an outlet of the marine mining pipeline comprises:
defining, by the processor, a fixed flow velocity and a fixed particle concentration for the inlet of the marine mining pipeline; and
defining, by the processor, a fixed pressure for the outlet of the marine mining pipeline.

7-8. (canceled)

9. An electronic device, comprising:
a memory, and
a processor, wherein
the electronic device is configured to execute a program stored in the memory to perform the pseudo-fluid model-based numerical simulation method according to claim 1.

10. A non-transitory computer-readable storage medium, storing a computer program, wherein the computer program is executed to perform the pseudo-fluid model-based numerical simulation method according to claim 1.
